(19) United States
(12) Patent Application Publication
(10) Pub. No.: US 2015/0195951 A1
(43) Pub. Date: Jul. 9, 2015

(54) COOLED ELECTRONIC ASSEMBLY AND COOLING DEVICE

(71) Applicant: GE Aviation Systems LLC, Grand Rapids, MI (US)

(72) Inventors: Dan Scott Long, San Antonio, TX (US); Michael Carl Ludwig, Margate, FL (US); Michael Pietrantonio, Winter Springs, FL (US)

(73) Assignee: GE Aviation Systems LLC, Grand Rapids, MI (US)

(21) Appl. No.: 14/147,665

(22) Filed: Jan. 6, 2014

(51) Int. Cl. H05K 7/20

(52) U.S. Cl. CPC H05K 7/2039; H05K 7/20272

(57) ABSTRACT

A cooling device and a cooled electronic assembly having a substrate having a first coefficient of thermal expansion, at least one heat source operably coupled to the substrate, a carrier plate operably coupled to the substrate and a heat sink wherein the heat sink, carrier plate, and substrate are configured to direct heat away from the at least one heat source.

### BACKGROUND OF THE INVENTION

Contemporary electronics produce heat that may result in thermal management problems. Heat must be removed from the electronic device to improve reliability and prevent premature failure of the electronics. Heat exchangers or heat sinks may be employed to dissipate the heat generated by the electronics; however, the beneficial functions may be contrary to maintaining or reducing the weight of the product or reducing its cost.

One method for cooling such power electronics is by utilizing dry or wet heat sinks. The heat sinks operate by transferring the heat away from the power electronics thereby maintaining a lower thermal resistance path. There are various types of heat sinks known in thermal management fields including air-cooled and liquid-cooled devices.

### BRIEF DESCRIPTION OF THE INVENTION

In one aspect, an embodiment of the invention relates to a cooled electronic assembly having a substrate having a first coefficient of thermal expansion, at least one heat source operably coupled to the substrate, a carrier plate operably coupled to the substrate and having a second coefficient of thermal expansion that matches the first coefficient of thermal expansion, and a heat sink, comprising a base plate, operably coupled to the carrier plate. The heat sink, carrier plate, and substrate are configured to direct heat away from the at least one heat source.

In another aspect, an embodiment of the invention relates to a cooling device for cooling at least one heat source mounted on a substrate having a first coefficient of thermal expansion, having a carrier plate operably coupled to the substrate and having a second coefficient of thermal expansion that matches the first coefficient of thermal expansion and a heat sink, comprising a base plate, selectively operably coupled to the carrier plate wherein the heat sink and carrier plate are configured to direct heat away from the at least one heat source.

### BRIEF DESCRIPTION OF THE DRAWINGS

In the drawings:

FIG. 1 is a perspective view of a cooled electronic assembly according to an embodiment of the invention;

FIG. 2 is an exploded perspective view of the cooled electronic assembly of FIG. 1; and

FIG. 3 is a cross-sectional view of the cooled electronic assembly of FIG. 1.

FIG. 4 is a cross-sectional view of a cooled electronic assembly according to another embodiment of the invention.

### DESCRIPTION OF EMBODIMENTS OF THE INVENTION

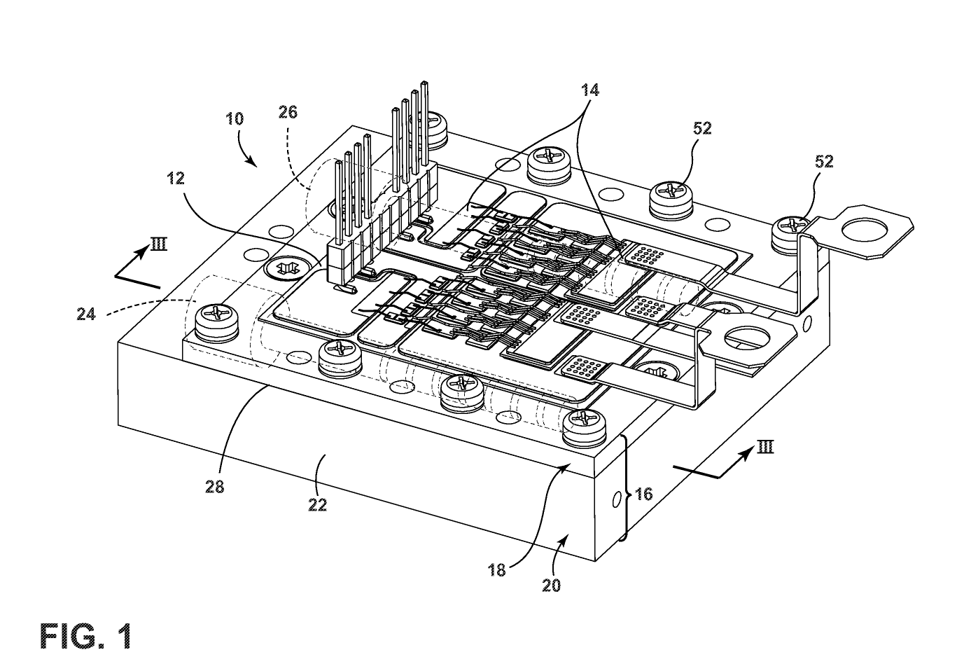

FIG. 1 illustrates a cooled electronic assembly 10 having a substrate 12, at least one heat source 14 operably coupled to the substrate 12 and a cooling device 16 including a carrier plate 18 and a heat sink 20. The substrate 12 may be formed from any suitable material and may have a first coefficient of thermal expansion.

It will be understood that any suitable number of heat sources 14 may be operably coupled to the substrate 12. The heat source(s) 14 may be mounted to the substrate 12 in any suitable manner including that the heat source(s) 14 may be mechanically coupled to the substrate 12 including that a thermal conductive adhesive or solder may be used.

The heat source(s) 14 may include an electronic device or power electronics coupled on the substrate 12. The cooled electronic assembly 10 may be utilized with any heat sources (14) that require a cooling medium for thermal management such as electronic components that require a uniform temperature distribution due to sensitivity with thermal expansion effects. For example, the cooled electronic assembly 10 may be used with both airborne and ground based electronics. Non-limiting examples of the power electronics or heat source(s) 14 may include Insulated Gate Bipolar Transistors (IGBT), Metal Oxide Semiconductor Field Effect Transistors (MOSFET), Diodes, Metal Semiconductor Field Effect Transistors (MESFET), and High Electron Mobility Transistors (HEMT).

The carrier plate 18 may be operably coupled to the substrate 12. For example, the carrier plate 18 may be bonded directly to the substrate 12. The bonding material may include any suitable bonding material such as an adhesive or solder. It may have a coefficient of thermal expansion of variable performance and for example it may have a coefficient of thermal expansion ranging from 4-9 parts per million/° C. The carrier plate 18 has a second coefficient of thermal expansion that matches the first coefficient of thermal expansion of the substrate 12. The term “match” as used herein does not require that the coefficients of thermal expansion are an identical match. Instead, the coefficients of thermal expansion must match within an acceptable range of parts per million per ° C. It is contemplated that the coefficients of thermal expansion match if they are within 80 parts per million/° C. of each other.

In certain embodiments, the carrier plate 18 may comprise at least one thermally conductive material, non-limiting examples of which may include copper, aluminum, nickel, molybdenum, titanium, and alloys thereof including a molybdenum copper alloy. In some examples, the carrier plate 18 may also comprise at least one thermally conductive material, non-limiting examples of which may include thermo pyrolytic graphite (TPG). In other examples, the carrier plate 18 may also comprise at least one thermally conductive material, non-limiting examples of which may include metal matrix composites such as aluminum silicon carbide (AlSiC), aluminum graphite, or copper graphite. Alternatively, the carrier plate 18 may also comprise at least one thermally conductive material, non-limiting examples of which may include ceramics such as aluminum oxide, aluminum nitride, or silicon nitride ceramic. In certain examples, the carrier plate 18 may include at least one thermoplastic material.

The heat sink 20 may include a baseplate 22, operably coupled to the carrier plate 18. The base plate 22 may be formed in any suitable manner including machining it from a solid metal blank. For example, the heat sink 20 may be machined from aluminum or another metal depending on the thermal requirements. The heat sink 20 may define an inlet 24 and an outlet 26 within the baseplate 22. In the illustrated example, both the inlet 24 and the outlet 26 are recessed downwardly from an upper surface 28 of the heat sink 20. In embodiments of the invention, the inlet 24 is configured to receive a coolant, and the outlet 26 is configured to exhaust the coolant. It will be understood that the heat sink 20 may be a liquid-cooled heat sink 20. In certain embodiments, non-limiting examples of the liquid coolant may include ethylene glycol, propylene glycol, and polyalphaolefin.

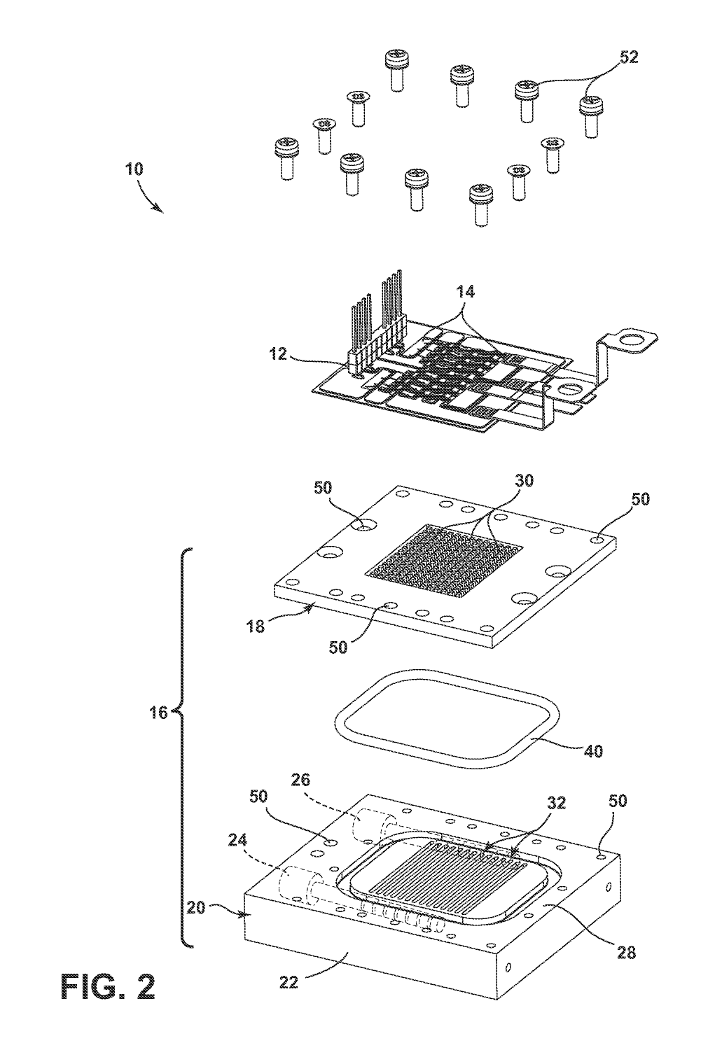

As illustrated more clearly in FIG. 2, the carrier plate 18 may include millichannels 30 configured to deliver a coolant for cooling the heat source(s) 14. Further, the heat sink 20 includes millichannels 32 configured to deliver a coolant to the carrier plate 18 for cooling the heat source(s) 14. More specifically, the heat sink 20 may define a plurality of millichannels 32 arranged parallel to each other and configured to communicate fluidly with the inlet 24 and outlet 26.

The millichannels 30 and 32 may be formed in any suitable manner including that they may be cast, machined, or etched into the carrier plate 18 and the heat sink 20, respectively. The millichannels 30 and 32 may be shaped in any suitable manner such that they are configured to deliver the coolant, preferably uniformly, to improve thermal removal performance. More specifically, the millichannels 30 and 32 may be in fluid communication with the substrate 12 once it is operably coupled to the carrier plate 18. A discussion of millichannels is disclosed in U.S. Pat. No. 7,898,807, which is incorporated herein by reference.

As illustrated, the cooling device 16 may also include a seal 40 for sealing the carrier plate 18 to heat sink 20. The seal 40 may be any suitable seal including the illustrated o-ring. The seal 40 may be selected for high temperature and fluid resistance properties. For example, the seal 40 may be formed from any suitable material including rubber or a material suitable for use with coolants including ethylene glycol, propylene glycol, and polyalphaolefin.

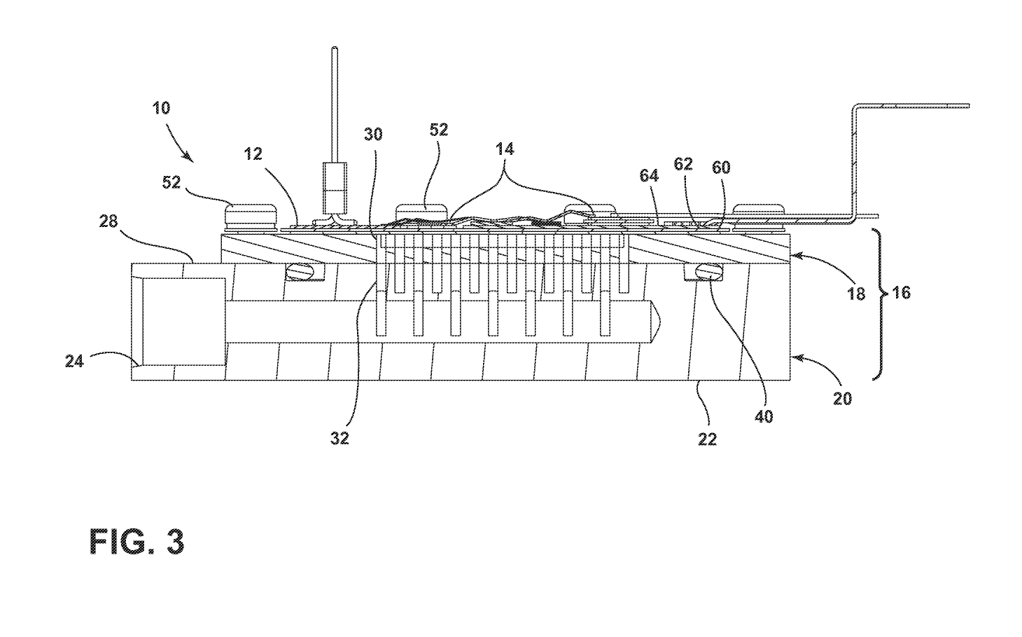

As illustrated more clearly in FIG. 3, the substrate 12 may include multiple layers including for example, a lower layer 60 (a first layer), a middle layer 62 (a second layer), and an upper layer 64 (a third layer). For the arrangement in FIG. 3, the substrate 12 is coupled to the carrier plate 18 by attaching the lower layer 60 to the carrier plate 18. The heat source(s) 14 are coupled to the substrate 12 by attaching the heat source(s) 14 to the upper layer 64.

In some embodiments, the middle layer 62 may comprises at least one electrically isolating and thermally conductive layer. The upper layer 64 and lower layer 60 may comprise at least one conductive material, respectively. In one non-limiting example, the middle layer 62 is a ceramic layer, and the upper and lower layers 64, 60 may comprise metal, such as copper attached to the middle layer 62. Thus, the substrate 12 may have either a direct bonded copper (DBC), or an active metal braze (AMB) structure. The DBC and AMB refer to processes which copper layers are directly bonded to a ceramic layer.

Non-limiting examples of the middle layer 62 may comprise aluminum oxide (Al₂O₃), aluminum nitride (AlN), beryllium oxide (BeO), and silicon nitride (Si₃N₄ or SiN). Both the DBC and the AMB may be convenient structures for the substrate 12, and the use of the conductive material (in this case, copper) on the ceramic layer 62 may provide thermal and mechanical stability. Alternatively, the upper and lower layers 64, 60 may include other conductive materials, but not limited to, aluminum, gold, silver, and alloys thereof according to different applications. Even though the substrate 12 may have multiple layers its coefficient of thermal expansion may be based on one of the layers. In the above example, if the middle layer 62 is composed of aluminum nitride the coefficient of thermal expansion for the substrate may be that of aluminum nitride, which may also be mounted on carriers made out of different material as well.

The substrate 12 may be attached to the carrier plate 18 and the heat source(s) 14 using a number of techniques, including but not limited to, brazing, bonding, diffusion bonding, soldering, or pressure contact such as clamping, which provides a simple assembly process, which reduces the overall cost of the cooled electronic assembly 10. The carrier plate 18 with the attached substrate 12 may be fastened together with the heat sink 20 in any suitable manner. In the illustrated example, the heat sink 20 and carrier plate 18 have been illustrated as including openings 50 (FIG. 2) in which screws 52 may be inserted to fasten the heat sink 20 and carrier plate 18. Alternatively, other methods for fastening may also be used including the use of an adhesive or brazing. In the case of an adhesive, a thermally conductive compound may be used to bond the heat sink 20 and the carrier plate 18. While the substrate 12, carrier plate 18, and heat sink 20 have all been illustrated as having square configurations, it will be understood that they may be formed in any suitable manner with any suitable shape. Thus, it will be understood that they may take alternative forms including circular, rectangular, etc.

During operation, the heat sink 20, carrier plate 18, and substrate 12 are configured to direct heat away from the at least one heat source. More specifically, the carrier plate 18 and a heat sink 20 cooperate with each other to direct one or more coolants to cool the heat source(s) 14. The coolant can enter the inlet 24, then flow through the millichannels 32 and 30 where the fluid may be in communication with the substrate 12, and finally enter the outlet 26. Thus, the heat generated from the heat source(s) 14 may be removed by the coolant, thereby cooling the electronics.

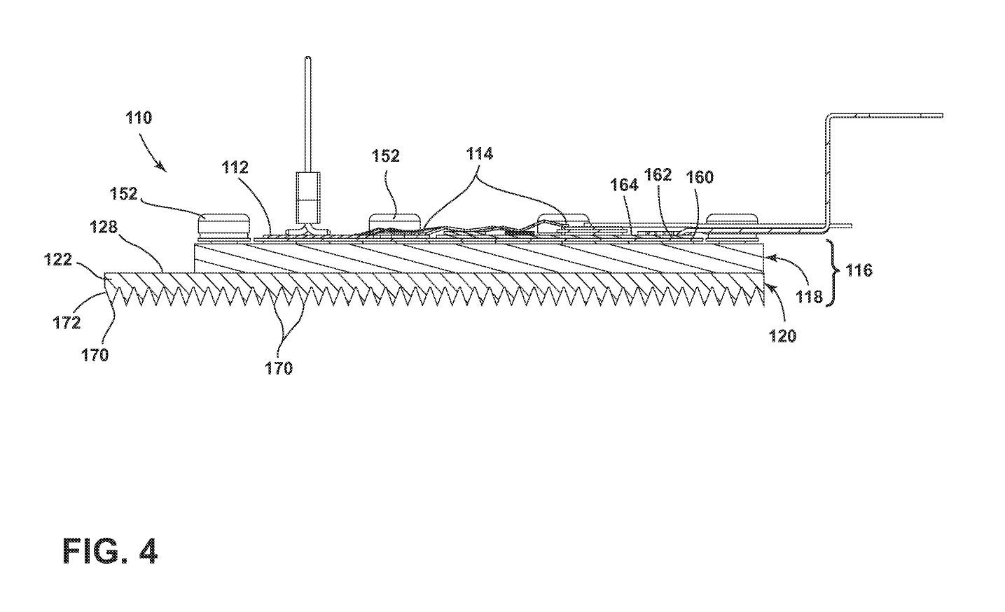

FIG. 4 illustrates an alternative heat sink 120 that may be utilized within a cooled electronic assembly 110. The cooled electronic assembly 110 is similar to the cooled electronic assembly 10 previously described. Therefore, like parts will be identified with like numerals increased by 100, and it is understood that the description of like parts of the cooled electronic assembly 10 applies to the cooled electronic assembly 110, unless otherwise noted.

One difference between them is that the heat sink 120 of the cooled electronic assembly 110 is an air-cooled heat sink 120. Thus, the inlets and outlets and the internal channels have not been included within the heat sink 120. Further, the air-cooled heat sink 120 has been illustrated as including a plurality of heat dissipating fins 170. The plurality of heat-dissipating fins 170 may project from the heat sink 120 and are illustrated as projecting from a bottom 172 of the heat sink 120. The heat-dissipating fins 170 may be formed in any suitable manner including that they may be formed with the remainder of the heat sink 120 or may be formed by machining. The heat-dissipating fins 170 increase the exterior surface area of the heat sink 120 allowing more heat to be transferred to the surrounding air through convection.

During operation, the heat conducted through the carrier plate 118 is directly conducted to the exterior of the heat-dissipating fins 170. Heat may then be dissipated through convection into the air surrounding the heat-dissipating fins 170.

For any of the above embodiments it will be understood that the substrate, carrier plate, and heat sink may be formed from any suitable materials so long as the substrate and carrier plate have matching coefficients of thermal expansion. By way of specific non-limiting examples, the substrate 12 may be composed of aluminum nitride (AlN), which has a coefficient of thermal expansion of 5.3 parts per million/° C. and the carrier plate 18 may be composed of a molybdenum copper alloy (70Mo/30Cu), which has a coefficient of thermal expansion of 4.8 parts per million/° C. The coefficient of thermal expansion of the molybdenum copper alloy matches that of the aluminum nitride. Further, the heat sink 20 may be composed of aluminum (Al), which has a coefficient of thermal expansion of 23.1 parts per million/° C. and thus does not have a coefficient of thermal expansion that matches the coefficient of thermal expansion of the molybdenum copper alloy or aluminum nitride.

The embodiments described above provide a variety of benefits including solving thermal management problems associated with cooling electronics devices and provides a disposable interface that may be utilized between the heat sink and the substrate. Previous devices utilized a heat sink made of an expensive material to match the coefficient of thermal expansion of the substrate, where the substrate and heat sink were bonded directly together. In such an instance, the substrate and heat sink were integral once joined together and the entire device had to be discarded entirely if the substrate becomes damaged. The above-described embodiments reduce the cost of the cooling device and the cooled electronic assembly as the heat sink is no longer required to be made of expensive materials having a coefficient of thermal expansion that matches the substrate. The above-described embodiments have both a lower cost to product and a lower cost to repair. More specifically, the above described embodiments bond the substrate directly to a carrier plate that is fabricated from material that matches the substrate coefficient of thermal expansion, this in turn uses less of that material and is relatively simple to machine. Should the substrate fail the heat sink component may be reused.

To the extent not already described, the different features and structures of the various embodiments may be used in combination with each other as desired. Some features may not be illustrated in all of the embodiments, but may be implemented if desired. Thus, the various features of the different embodiments may be mixed and matched as desired to form new embodiments, whether or not the new embodiments are expressly described. All combinations or permutations of features described herein are covered by this disclosure.

This written description uses examples to disclose the invention, including the best implementation, to enable any person skilled in the art to practice the invention, including making and using the devices or systems described and performing any incorporated methods presented. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A cooled electronic assembly, comprising:
a substrate having a first coefficient of thermal expansion;
at least one heat source operably coupled to the substrate;
a carrier plate operably coupled to the substrate and having a second coefficient of thermal expansion that matches the first coefficient of thermal expansion; and
a heat sink, comprising a base plate, operably coupled to the carrier plate;
wherein the heat sink, the carrier plate, and the substrate are configured to direct heat away from the at least one heat source.

2. The cooled electronic assembly of claim 1 wherein the heat sink is a liquid-cooled heat sink.

3. The cooled electronic assembly of claim 2 wherein the liquid cooled heat sink further comprises millichannels configured to deliver a coolant to the carrier plate for cooling the at least one heat source.

4. The cooled electronic assembly of claim 3 wherein the carrier plate further comprises millichannels configured to deliver the coolant for cooling the at least one heat source.

5. The cooled electronic assembly of claim 1 wherein the heat sink is an air-cooled heat sink having a plurality of heat dissipating fins.

6. A cooling device for cooling at least one heat source mounted on a substrate having a first coefficient of thermal expansion, comprising:
a carrier plate operably coupled to the substrate and having a second coefficient of thermal expansion that matches the first coefficient of thermal expansion; and
a heat sink, comprising a base plate, selectively operably coupled to the carrier plate;
wherein the heat sink and the carrier plate are configured to direct heat away from the at least one heat source.

7. The cooling device of claim 6 wherein the heat sink is a liquid-cooled heat sink that utilizes a coolant for transferring heat from the at least one heat source.

8. The cooling device of claim 7 wherein the liquid cooled heat sink further comprises millichannels configured to deliver the coolant to the carrier plate for cooling the at least one heat source.

9. The cooling device of claim 8 wherein the carrier plate further comprises millichannels configured to deliver the coolant for cooling the at least one heat source.

10. The cooling device of claim 7, further comprising a seal for sealing the carrier plate to the heat sink.

11. The cooling device of claim 10 wherein the seal is an o-ring suitable for use with coolants including ethylene glycol, propylene glycol, and polyalphaolefin.

12. The cooling device of claim 6 wherein the substrate is composed of aluminum nitride and the carrier plate is composed of a molybdenum copper alloy.

13. The cooling device of claim 12 wherein the heat sink is composed of aluminum and does not have a coefficient of thermal expansion that matches the first coefficient of thermal expansion.

14. The cooling device of claim 6 wherein the heat sink is an air-cooled heat sink having a plurality of heat dissipating fins.

15. The cooling device of claim 6 wherein the carrier plate is bonded directly to the substrate.
